(19) United States
(12) Patent Application Publication
(10) Pub. No.: US 2015/0262791 A1
(43) Pub. Date: Sep. 17, 2015

(54) ELECTRON BEAM DRAWING METHOD, ELECTRON BEAM DRAWING APPARATUS AND DATA GENERATING METHOD

(71) Applicant: KABUSHIKI KAISHA TOSHIBA, Tokyo (JP)

(72) Inventor: Keisuke YAGAWA, Yokohama Kanagawa (JP)

(73) Assignee: KABUSHIKI KAISHA TOSHIBA

(21) Appl. No.: 14/481,951

(22) Filed: Sep. 10, 2014

(30) Foreign Application Priority Data
Mar. 13, 2014 (JP) 2014-050818

(51) Int. Cl. H01J 37/317; H01J 37/302; H01J 37/147; H01J 37/304

(52) U.S. Cl. CPC H01J 37/3174; H01J 37/304; H01J 37/3023; H01J 37/1472

(57) ABSTRACT

An electron beam drawing method is an electron beam drawing method for manufacturing a lithography original plate in a variable shaped beam method. The electron beam drawing method includes extracting a hot spot in a circuit pattern layout of the lithography original plate at which a circuit pattern in the circuit pattern layout and a preset hot spot drawing pattern agree with each other. The electron beam drawing method further includes generating drawing data representing the circuit pattern layout with at least a part of the circuit pattern at the extracted hot spot replaced with a relieving drawing pattern. The electron beam drawing method further includes performing drawing on a resist applied to the substrate in the variable shaped beam method based on the drawing data.

### CROSS-REFERENCE TO RELATED APPLICATION

This application is based upon and claims the benefit of priority from the prior Japanese Patent Application No. 2014-050818, filed on Mar. 13, 2014, the entire contents of which are incorporated herein by reference.

### BACKGROUND

1. Field

Embodiments described herein relate generally to an electron beam method, electron beam drawing apparatus, and a data generating method.

2. Background Art

A lithography process using an electron beam drawing apparatus is a known technique of manufacturing a photomask used in a semiconductor device manufacturing process.

### BRIEF DESCRIPTION OF THE DRAWINGS

FIG. 1 is a diagram showing an example of a configuration of a variable shaped beam type electron beam drawing apparatus 100 according to a first embodiment;

FIG. 2 is a flowchart showing an example of the electron beam drawing method using the electron beam drawing apparatus 100 shown in FIG. 1;

FIG. 3 is a diagram showing an example of an evaluation pattern in which continuous drawing parts disposed adjacent to line patterns have different widths;

FIG. 4 is a diagram showing another example of the evaluation pattern in which continuous drawing parts disposed adjacent to line patterns have different widths;

FIG. 5 is a diagram showing a hot spot drawing pattern and a relieving drawing pattern to replace the hot spot drawing pattern;

FIG. 6 is a diagram showing the amount of accumulated energy of the electron beam in the case where drawing is conducted after the hot spot drawing pattern is replaced with the relieving drawing pattern;

FIG. 7 is a diagram for illustrating extraction of a hot spot at which the hot spot drawing pattern exists on the lithography original plate and replacement of the circuit pattern with the extracted hot spot with the relieving drawing pattern;

FIG. 8 is a diagram showing an example of CAD data and a beam profile for the variable shaped beam method in the case where the LS pattern is large;

FIG. 9 is a diagram showing an example of CAD data and a beam profile for the variable shaped beam method in the case where the LS pattern is small;

FIG. 10 is a diagram showing a drawing pattern including continuous drawing parts adjacent to a drawing part corresponding to LS patterns, the amount of accumulated energy and a resist pattern developed on a substrate “W”;

FIG. 11 is a diagram showing a drawing pattern including relieving drawing patterns adjacent to a drawing part corresponding to LS patterns, the amount of accumulated energy and a resist pattern developed on a substrate “W”.

### DETAILED DESCRIPTION

An electron beam drawing method includes extracting a hot spot in a circuit pattern layout of the lithography original plate at which a circuit pattern in the circuit pattern layout and a preset hot spot drawing pattern agree with each other. The electron beam drawing method further includes generating drawing data representing the circuit pattern layout with at least a part of the circuit pattern at the extracted hot spot replaced with a relieving drawing pattern. The electron beam drawing method further includes performing drawing on a resist applied to the substrate in the variable shaped beam method based on the drawing data. The hot spot drawing pattern includes first space patterns that are successively scanned with an electron beam and first line patterns that are adjacent to the first space patterns and are not scanned with the electron beam. The relieving drawing pattern has the same size as the first space patterns and includes a second space pattern that is scanned with the electron beam. The second space pattern includes a plurality of slits that are not scanned with the electron beam.

As semiconductor devices have greater capacities, finer photomasks, extreme ultraviolet (EUV) masks or nanoimprint templates are required to be used in the lithography process.

In particular, the minimum pattern dimension required templates of EUV and nanoimprint lithography (NIL), which are next-generation lithography techniques, is 20 nm or less in terms of half pitch “hp”.

The precision of conventional photomask manufacturing processes is limited to approximately 50 nm, which is required for sub resolution assist features (SRAF). Therefore, it is required to develop a manufacturing method usable for next-generation lithography techniques.

In particular, a technical challenge in development of the manufacturing method is to resolve a resist pattern. If the resist pattern is formed with an inadequate precision, a metal film or the like under the resist pattern cannot be processed with high precision.

The resist resolvability of an electron beam lithography is generally evaluated in terms of the resolving power of the electron beam and the resolving power of the resist process in development of the resist material.

For example, in manufacturing of a conventional photomask, a variable shaped beam (VSB) type drawing apparatus is typically used. The VSB drawing apparatus is inferior in resolving power to a spot beam drawing apparatus, which can narrow down the beam to 2 to 4 nm, but is superior in throughput: the VSB drawing apparatus is capable of drawing a pattern having a size of about 500 nm in one shot.

On the other hand, the spot beam drawing apparatus having a higher resolving power is more suitable for forming a resist pattern having a half pitch of 20 nm or less. However, the spot beam drawing apparatus is inferior in throughput and therefore in practicability and productivity.

In view of such circumstances, there is a demand for a VSB drawing apparatus that is capable of forming a pattern having a half pitch of 20 nm or less.

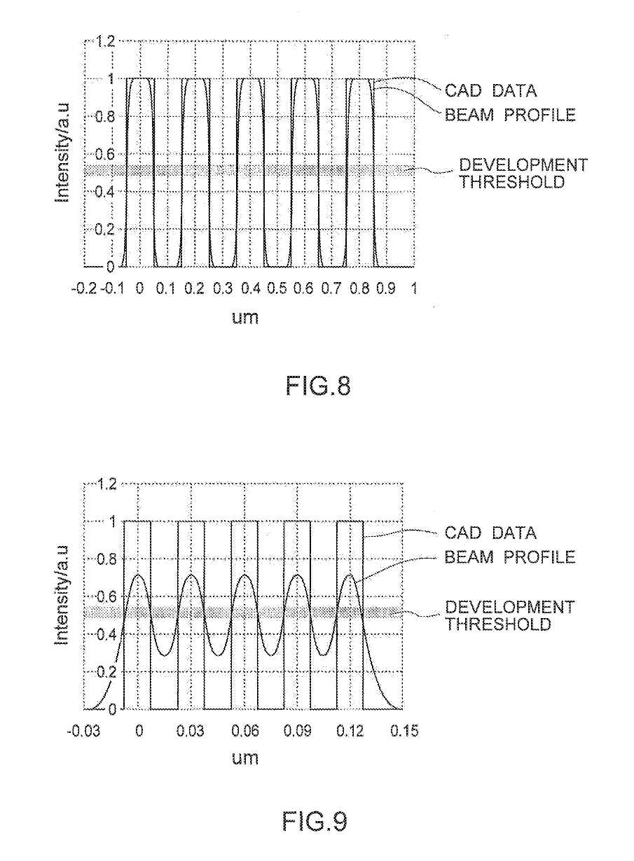

FIG. 8 is a diagram showing an example of CAD data and a beam profile for the variable shaped beam method in the case where the LS pattern is large. FIG. 9 is a diagram showing an example of CAD data and a beam profile for the variable shaped beam method in the case where the LS pattern is small.

FIG. 8 shows a result of simulation of the amount of electrons incident on a substrate in the case where the beam resolving power is 10 nm, and five LS patterns having a half pitch of 100 nm are drawn. FIG. 9 shows a result of simulation of the amount of electrons incident on a substrate in the case where the beam resolving power is 10 nm, and five LS patterns having a half pitch of 15 nm are drawn. In FIGS. 8 and 9, the vertical axis indicates the intensity of the incident electrons, and the horizontal axis indicates the distance across the patterns.

As shown in FIGS. 8 and 9, the beam profile of the VSB drawing apparatus is represented as an error function, which is a Gaussian convolution function. That is, the beam profile is planar with respect to the CAD data (design data).

In particular, as shown in FIG. 9, for the LS patterns having a half pitch of 15 nm for which the beam resolving power is insufficient, the beam profile includes wider beam bottoms.

As a result, the bottoms of the adjacent beams overlap with each other, and energy is accumulated in a non-drawing part.

If the drawing technique for photomasks is used, the energy contrast between the drawing part and the non-drawing part is insufficient, and the process margin is extremely small.

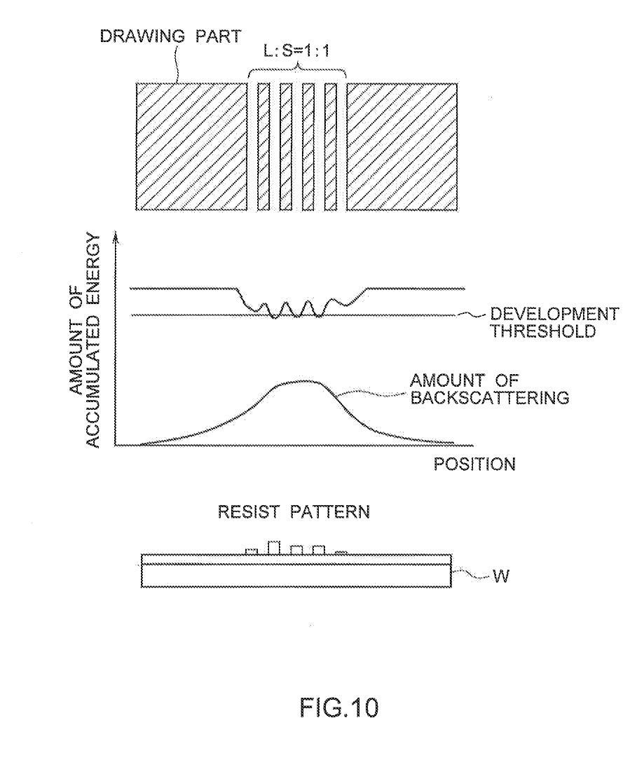

FIG. 10 is a diagram showing a drawing pattern including continuous drawing parts adjacent to a drawing part corresponding to LS patterns, the amount of accumulated energy and a resist pattern developed on a substrate “W”. In the example shown in FIG. 10, the ratio between line (L) and space (S) of the LS pattern is 1:1.

If the amount of accumulated energy of the electron beam exceeds a development threshold, the resist applied to the substrate “W” is exposed to enough light to be removed in development. On the other hand, if the amount of accumulated energy of the electron beam does not exceed the development threshold, the resist applied to the substrate “W” is inadequately exposed to light and therefore is not removed in development.

As shown in FIG. 10, in the case where the pattern adjacent to a line pattern having a line width of 15 nm is a continuous region, backscattering has a greater influence. In manufacturing of the conventional photomasks, the beam resolving power is adequate for any desired pattern, so that the pattern can be resolved by suppressing the amount of irradiation of the electron beam by proximity effect correction, even if there is an influence of backscattering in the surrounding region.

However, as the size of the LS pattern to be formed comes close to the beam resolving power, even if the LS pattern can be formed, a part of the pattern that is locally strongly affected by the backscattering has an inadequate contrast.

Even though the amount of irradiation can be suppressed by proximity effect correction, the contrast degraded by the backscattering cannot be improved by proximity effect correction. Therefore, it is impossible to form the part by adjusting the amount of irradiation.

In addition, in formation of a fine pattern, the initial film thickness is inevitably small because of the aspect ratio that allows formation of the resist pattern, and the small resist thickness poses a problem of degradation of the functionality of the resist as a mask in processing of the base material.

The problem can be avoided if the continuous drawing parts shown in FIG. 10 have a configuration similar to that of the LS part in the middle,

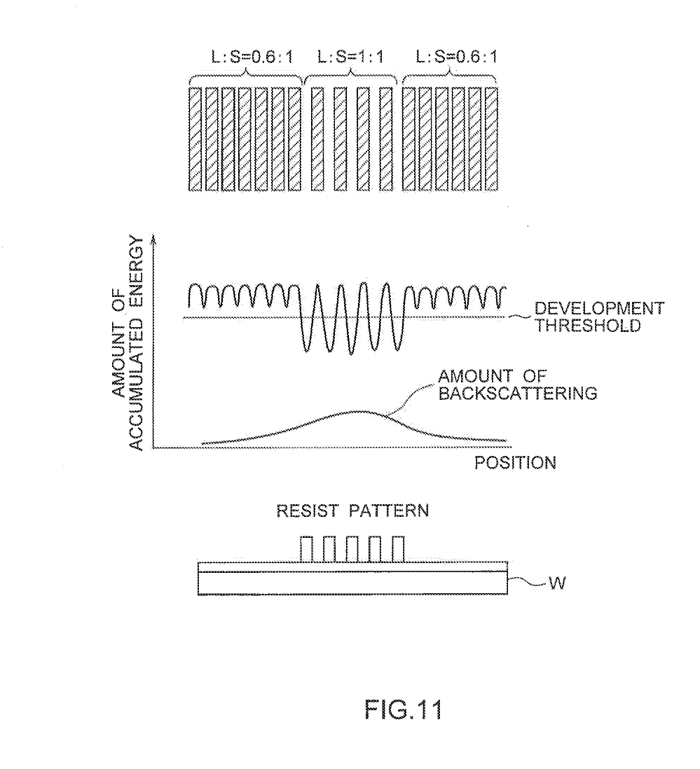

FIG. 11 is a diagram showing a drawing pattern including relieving drawing patterns adjacent to a drawing part corresponding to LS patterns, the amount of accumulated energy and a resist pattern developed on a substrate “W”. In the example shown in FIG. 11, the ratio between line (L) and space (S) of the LS pattern is 1:1, and the ratio between line (L) and space (5) of the relieving drawing pattern is 0.6:1,

As shown in FIG. 11, in the energy profile in the case where the relieving patterns are disposed, since the continuous drawing parts have a reduced coverage, the amount of backscattering in the line parts “L” from the surrounding regions is reduced.

Therefore, the profile contrast of the LS patterns in the middle part is improved.

Since the relieving pattern has to produce a desired continuous drawing part after development, the amount of energy accumulated in the slit pattern used as the relieving pattern is required to exceed the development threshold. As far as the requirement is satisfied, the influence of the backscattering on the surrounding region can be more significantly suppressed than conventional, and the relieving pattern can have a configuration similar to that of the LS patterns in the middle part.

In an embodiment, an example of the electron beam drawing method that is improved in precision of formation of a resist pattern based on the principle shown in FIG. 11 will be described.

In the embodiment below, there will be described a case where data processings including evaluation of a hot spot drawing pattern, extraction of a hot spot, evaluation of a relieving drawing pattern and generation of drawing data are performed in an electron beam drawing apparatus.

However, the data processings including evaluation of a hot spot drawing pattern, extraction of a hot spot, evaluation of a relieving drawing pattern and generation of drawing data may be performed by an external CPU or the like, and the resulting drawing data may be input to an electron beam drawing apparatus 100. That is, generation of data used for manufacturing a lithography original plate in the variable shaped beam method is performed by a CPU or the like external to the electron beam drawing apparatus.

In the following, the embodiment will be described with reference to the drawings.

### First Embodiment

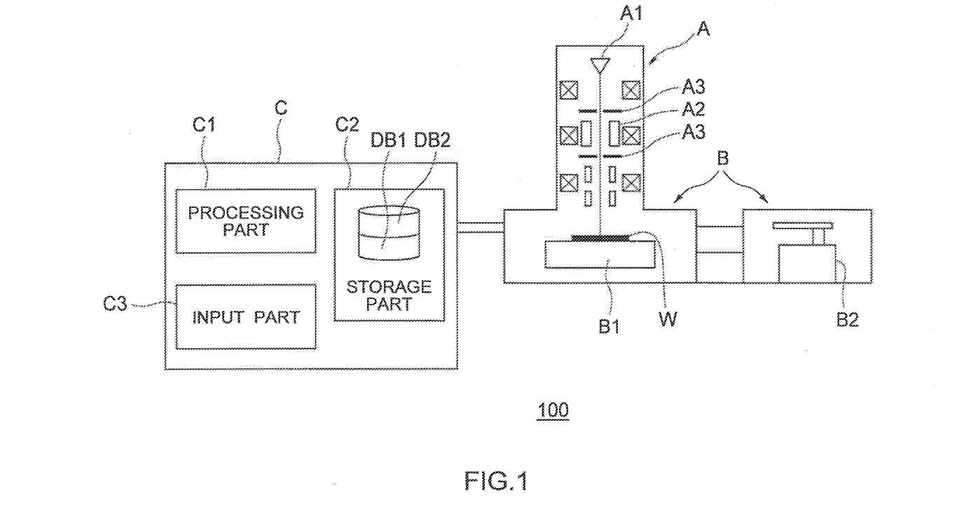

FIG. 1 is a diagram showing an example of a configuration of a variable shaped beam type electron beam drawing apparatus 100 according to a first embodiment.

As shown in FIG. 1, the variable shaped beam type electron beam drawing apparatus 100 includes an electro-optical unit “A”, a mechanical unit “B” and a control unit “C”.

The electro-optical unit “A” includes an electron gun “A1”, a deflector “A2” and a shaping aperture “A3”, for example. In the electro-optical unit “A”, the electron gun “A1” outputs an electron beam, the shaping aperture “A3” shapes the electron beam, and the deflector “A2” deflects the shaped electron beam to irradiate a substrate “W” with the electron beam.

The mechanical unit “B” includes a conveying part “B2” that conveys the substrate “W”, and a stage “B1” onto which the substrate “W” is conveyed and mounted. An electron beam sensitive resist is applied to the substrate “W”.

The mechanical unit “B” controls the conveying part “B2” to mount the substrate “W” on the stage “B1” or remove the substrate “W” from the stage “B1”.

The mechanical unit “B” also controls operation of the stage “B1” so as to irradiate a predetermined part of the substrate “W” mounted on the stage “B1” with the electron beam.

The control unit “C” controls the electro-optical unit “A” and the mechanical unit “B”.

The control unit “C” includes a processing part “C1”, a storage part “C2” and an input part “C3”.

The input part “C3” is configured to receive drawing data, which is data readable by a drawing apparatus converted from a circuit pattern layout of a lithography original plate, and a condition for electron beam irradiation, for example.

The storage part “C2” includes a first database “DB1” and a second database “DB2”.

The storage part “C2” stores the drawing data corresponding to the circuit pattern layout of the lithography original plate and the condition for electron beam irradiation, for example. In particular, the first database “DB1” stores a hot spot drawing pattern, and the second database “DB2” stores a relieving drawing pattern.

As described above, the lithography original plate is a photomask, an EUV mask or a nanoimprint template.

The processing part “C1” perform processings of extracting a hot spot drawing pattern in the input drawing data and replacing the hot spot drawing pattern with the relieving drawing pattern.

Furthermore, the processing part “C1” decomposes the drawing data with the hot spot pattern replaced with the relieving pattern into rectangular or triangular shot graphics data having a size on the order of 1 μm or less, for example, which can be formed with an electron beam. The processing part “C1” of the control unit “C” generates in-drawing-apparatus data including a circuit pattern layout decomposed into shot graphics, the site of irradiation of the substrate “W” with the electron beam for each graphics and the irradiation amount, for example.

Based on the in-apparatus data generated by the processing part, the electro-optical unit “A” shapes, deflects or otherwise operates the electron beam to irradiate the substrate with the electron beam.

Based on the in-apparatus data, the mechanical unit “B” controls the position and operation of the drawing stage on which the substrate is held, in association with the electro-optical unit

When drawing on the substrate “W” based on the in-drawing-apparatus data is completed, the mechanical unit “B” conveys the substrate “W” out. The conveyed substrate “W” then undergoes processings, such as resist development and etching. In this way, a lithography original plate (a photomask) is completed.

Next, an example of an electron beam drawing method for the electron beam drawing apparatus 100 configured as described above to manufacture a lithography original plate in the variable shaped beam method will be described.

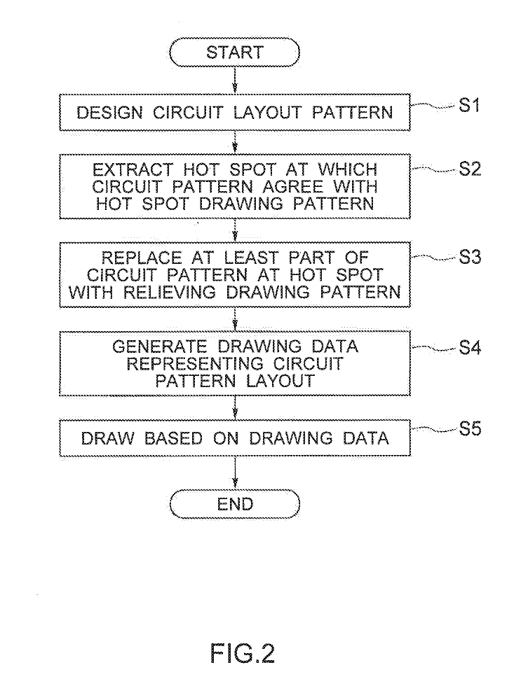

FIG. 2 is a flowchart showing an example of the electron beam drawing method using the electron beam drawing apparatus 100 shown in FIG. 1.

As shown in FIG. 2, first, a circuit pattern layout for a lithography original plate is designed according to a required semiconductor integrated circuit pattern (step “S1”).

The designed circuit pattern layout for the lithography original plate is input to the electron beam drawing apparatus 100 at the input part “C3” and stored in the storage part “C2” of the electron beam drawing apparatus 100.

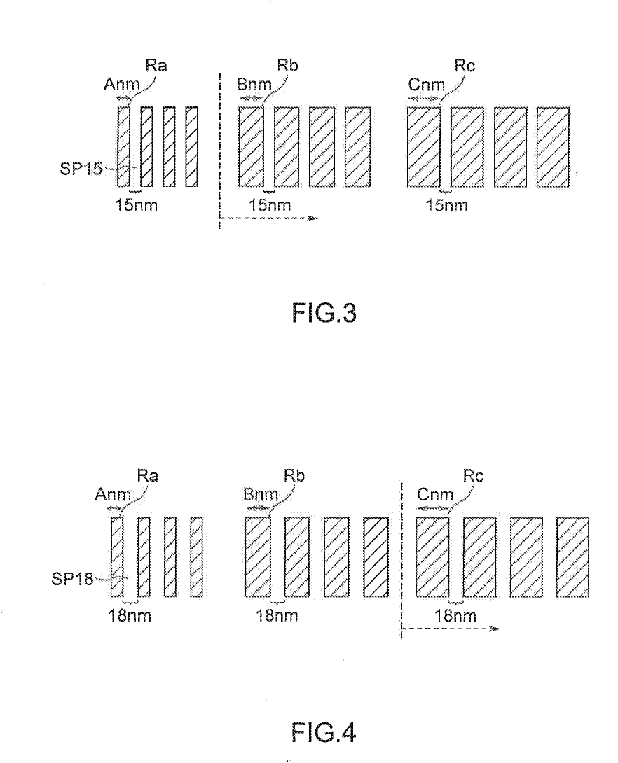

The processing part “C2” then performs processings of extracting a hot spot pattern and replacing the hot spot pattern with a relieving pattern. To this end, a DB of a hot spot pattern and a relieving pattern needs to be previously created by previous evaluation. A method of creating the DB is shown in FIGS. 3 and 4. FIG. 3 is a diagram showing an example of an evaluation pattern in which continuous drawing parts disposed adjacent to line patterns have different widths. FIG. 4 is a diagram showing another example of the evaluation pattern in which continuous drawing parts disposed adjacent to line patterns have different widths. In FIG. 3, the line patterns have a width of 15 nm. In FIG. 4, the line patterns have a width of 18 nm.

As shown in FIG. 3, drawing evaluation patterns for continuous drawing parts are set so that continuous drawing parts (space patterns) “Ra”, “Rb” and “Rc” adjacent to line patterns have different sizes (widths) (A nm, B nm and C nm) while the line patterns “SP15” in the circuit pattern have a fixed size (15 nm in this example). With these drawing evaluation patterns, the size of the space pattern that results in a defect in the line pattern is determined.

In the example shown in FIG. 3, the size (width) of the space pattern that results in a defect in the line pattern is B nm or greater. That is, in the case where the size (width) of the line patterns is 15 nm, patterns including the space patterns “Rb” and “Rc” having widths equal to or greater than B nm are hot spot drawing patterns.

In this case, the hot spot drawing patterns include first space patterns “Rb” or “Rc” that are successively scanned with the center of the electron beam in the irradiation direction thereof and first line patterns “SP15” that are adjacent to the first space patterns “Rb” or “Rc” and are not scanned with the center of the electron beam in the irradiation direction thereof.

In the example shown in FIG. 4, the size (width) of the space pattern that results in a defect in the line pattern “SP18” is C nm or greater. That is, in the case where the size (width) of the line patterns is 18 nm, patterns including the space patterns “Rc” having a width equal to or greater than C nm are hot spot drawing patterns.

In this case, the hot spot drawing patterns include first space patterns “Rc” that are successively scanned with the center of the electron beam in the irradiation direction thereof and first line patterns “SP18” that are adjacent to the first space patterns “Rc” and are not scanned with the center of the electron beam in the irradiation direction thereof.

In the case where the hot spot drawing pattern is drawn in the variable shaped beam method (in the case of evaluation of the hot spot drawing pattern), the amount of energy of the electron beam accumulated in the resist on the substrate “W” corresponding to the first line patterns is greater than a preset development threshold (FIG. 10).

The development threshold is an upper limit of the amount of the accumulated energy that allows the resist that is applied to the substrate “W” and exposed to light to be developed into a preset shape.

The conditions of electron beam irradiation in evaluation of the hot spot drawing pattern are the same as the conditions of electron beam irradiation in drawing based on the drawing data corresponding to the circuit pattern layout of the lithography original plate.

In the case where the hot spot drawing pattern is drawn in the variable shaped beam method (in the case of evaluation of the hot spot drawing pattern), the amount of energy of the electron beam accumulated in the resist on the substrate “W” corresponding to the first space patterns “Rc” is greater than the preset development threshold. That is, the resist is not shaped into a desired shape in development.

That is, the hot spot drawing pattern refers to a pattern designed so that the coverage can locally abruptly change and the resist pattern can collapse.

For example, the first database “DB1” of the storage part “C2” stores a relationship between the size (width) of a line pattern and the size (width) of a hot spot drawing pattern adjacent to the line pattern.

That is, hot spot drawing patterns having different pattern sizes are extracted, and a database of size conditions for the hot spot drawing patterns is stored in the storage part “C2”.

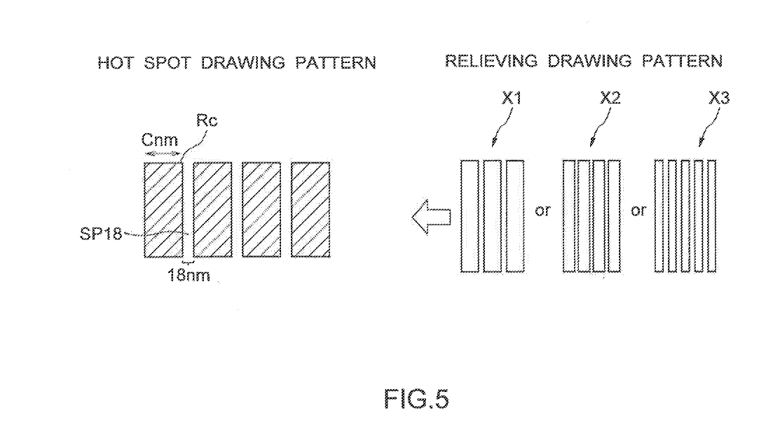

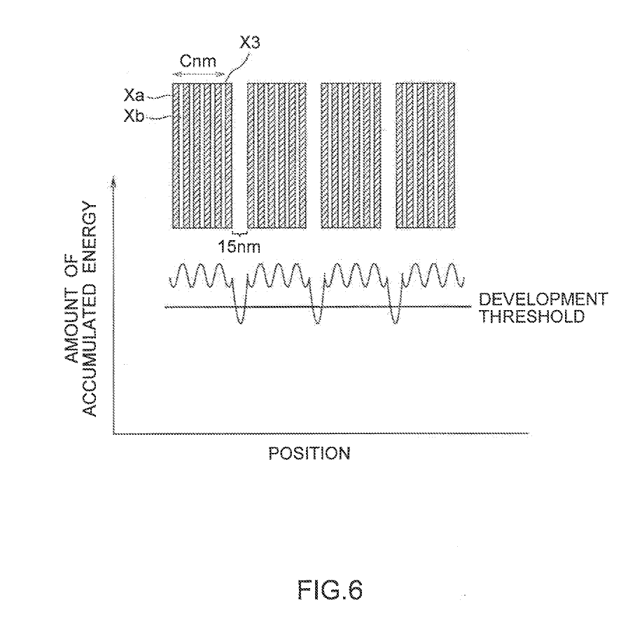

FIG. 5 is a diagram showing a hot spot drawing pattern and a relieving drawing pattern to replace the hot spot drawing pattern. FIG. 6 is a diagram showing the amount of accumulated energy of the electron beam in the case where drawing is conducted after the hot spot drawing pattern is replaced with the relieving drawing pattern.

As with the hot spot pattern, a plurality of slit patterns (“X1”, “X2” and “X3”, in this example) with reduced coverages are prepared, and evaluation is performed to determine an optimal relieving pattern.

The line pattern to which the relieving drawing pattern is adjacent is then drawn as shown in FIG. 6, and the precision of formation of the LS resist pattern is checked after development.

In the example shown in FIG. 6, in the case where the size (width) of the line pattern is 15 nm, a relieving drawing pattern “X3” is selected as an optimal one.

In the region corresponding to the relieving drawing pattern “X3”, the amount of accumulated energy of the electron beam is greater than the development threshold. Therefore, a predetermined continuous pattern (a continuous part in which the resist is removed) is formed.

On the other hand, in the region corresponding to the line pattern, the amount of accumulated energy of the electron beam is not greater than the development threshold because of the reduced coverage in the surrounding area.

In this way, for each of the sizes of the patterns included in the circuit pattern layout to be actually drawn, design conditions for relieving the hot spot pattern are previously evaluated by determining the size of the pattern that causes a defect in, or loss of, the resist adjacent to the pattern.

The condition under which the predetermined continuous drawing parts can be formed with the best precision is stored in the second database “DB2” of the storage part “C2” as an optimal condition for the relieving drawing pattern.

Referring back to FIG. 2, the processing part “C1” of the electron beam drawing apparatus 100 extracts a hot spot in the circuit pattern layout at which the drawing data based on the circuit pattern layout of the lithography original plate and the preset hot spot drawing pattern agree with each other (step “S2”).

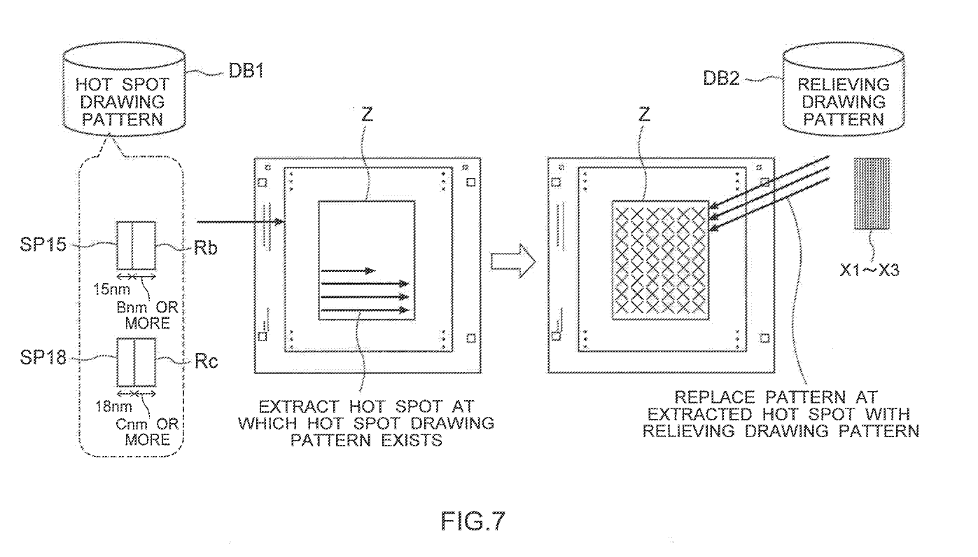

FIG. 7 is a diagram for illustrating extraction of a hot spot at which the hot spot drawing pattern exists on the lithography original plate and replacement of the circuit pattern with the extracted hot spot with the relieving drawing pattern.

As shown in FIG. 7, from the first database “DB1” storing the hot spot drawing pattern, an image of the hot spot drawing pattern is read out as a template. The image of the hot spot drawing pattern is scanned to match the image against a circuit pattern in a circuit pattern layout “Z” of the lithography original plate. Any part of the circuit pattern that matches with the hot spot drawing pattern is extracted as a hot spot in the layout of the lithography original plate.

As a method of extracting the hot spot drawing pattern, a matching method described in SPIE 8701, Photomask and Next-Generation Lithography Mask Technology XX, 87010C is used, for example.

As shown in FIG. 7, a relieving drawing pattern corresponding to the hot spot drawing pattern at the hot spot is then read from the second database “DB2”. A data processing is then performed to replace the circuit pattern at the hot spot that matches with the hot spot drawing pattern with the read relieving drawing pattern.

That is, as shown in FIG. 2, the processing part “C1” of the electron beam drawing apparatus 100 replaces at least a part of the circuit pattern at the extracted hot spot in the circuit pattern layout of the lithography original plate with the relieving drawing pattern (step “S3”).

For example, the processing part “C3” replaces a part of the hot spot drawing pattern at the hot spot that corresponds to the first space pattern “Rc” with the relieving drawing pattern “X3” (FIG. 6). In this case, the relieving drawing pattern “X3” has the same size as the first space pattern and includes a second space pattern “Xa” that is scanned with the center of the electron beam in the irradiation direction thereof, and the second space pattern “Xa” includes a plurality of slits “Xb” that are not scanned with the center of the electron beam in the irradiation direction thereof (FIG. 6).

For example, in the case where drawing is performed in the variable shaped beam method based on the drawing data, the amount of energy of the electron beam accumulated in the resist on the substrate “W” that is adjacent to the second space pattern and corresponds to the line pattern that is not scanned with the center of the electron beam is smaller than the development threshold (FIG. 11).

That is, the resist on the substrate “W” that corresponds to the line pattern is inadequately exposed to light and therefore is not developed and remains on the substrate “W”. The resist remaining on the substrate “W” serves as a mask when the substrate “W” is etched.

The size and interval of the slits of the relieving drawing pattern is set in such a manner that the amount of energy of the electron beam accumulated in the resist on the substrate that corresponds to the second space pattern is closest to the development threshold in the case where drawing is performed in the variable shaped beam method based on the drawing data.

That is, there is a condition under which, even if the drawing data indicates that there is a slit pattern, no resist remains in the slit pattern because of the beam resolution, that is, the amount of energy accumulated in the slit pattern in development is greater than the development threshold. As far as under the condition under which the amount of energy accumulated in development is greater than the development threshold, the desired continuous drawing part (space pattern) can be formed.

The slit pattern preferably has the largest size as far as the amount of accumulated energy is greater than the development threshold, in order to minimize the coverage and reduce the drawing time.

As shown in FIG. 2, the processing part “C1” of the electron beam drawing apparatus 100 then generates drawing data that represents the circuit pattern layout with at least a part of the circuit pattern at the extracted hot spot replaced with the relieving drawing pattern (step “S4”).

As shown in FIG. 2, the mechanical unit “B” of the electron beam drawing apparatus 100 then conveys the substrate “W” to which the electron beam sensitive resist is applied onto the stage “B1”. Drawing is then performed on the resist applied to the substrate “W” in the variable shaped beam method based on the in-drawing-apparatus data (step “S5”). The processing part “C1” derives the optimal irradiation amount from the drawing data by proximity effect correction calculation and fog correction calculation in the conventional manner.

After that, the mechanical unit “B” of the electron beam drawing apparatus 100 conveys the substrate out.

By using the electron beam drawing method described above, occurrence of a pattern defect in a local high-coverage part in fine pattern formation can be prevented, and a mask or template having a fine pattern can be manufactured.

That is, the electron beam drawing method according to this embodiment can improve the precision of formation of a resist pattern.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. An electron beam drawing method comprising:
extracting a hot spot in a circuit pattern layout of the lithography original plate at which a circuit pattern in the circuit pattern layout and a preset hot spot drawing pattern agree with each other,
generating drawing data representing the circuit pattern layout with at least a part of the circuit pattern at the extracted hot spot replaced with a relieving drawing pattern, and
performing drawing on a resist applied to the substrate in the variable shaped beam method based on the drawing data, and
wherein the hot spot drawing pattern
includes first space patterns that are successively scanned with an electron beam and first line patterns that are adjacent to the first space patterns and are not scanned with the electron beam, and
wherein the relieving drawing pattern
has the same size as the first space patterns and includes a second space pattern that is scanned with the electron beam, the second space pattern including a plurality of slits that are not scanned with the electron beam.

2. The electron beam drawing method according to claim 1, wherein a part of the circuit pattern at the hot spot that corresponds to the first space patterns of the hot spot drawing pattern is replaced with the relieving drawing pattern.

3. The electron beam drawing method according to claim 1, wherein in a case where the hot spot drawing pattern is drawn in the variable shaped beam method, the amount of energy of the electron beam accumulated in the resist on the substrate that corresponds to the first line patterns is greater than a preset development threshold, and
the development threshold is an upper limit value of the amount of accumulated energy that allows the resist applied to the substrate exposed to light to form a preset shape after development.

4. The electron beam drawing method according to claim 3, wherein in the case where the hot spot drawing pattern is drawn in the variable shaped beam method, the amount of energy of the electron beam accumulated in the resist on the substrate that corresponds to the first space patterns is greater than the development threshold.

5. The electron beam drawing method according to claim 1, wherein in the case where drawing is performed in the variable shaped beam method based on the drawing data, the amount of energy of the electron beam accumulated in the resist on the substrate that corresponds to the line patterns that are adjacent to the second space pattern and are not scanned with the electron beam is smaller than the development threshold.

6. The electron beam drawing method according to claim 1, wherein the size and interval of the slits of the relieving drawing pattern are set so that the amount of energy of the electron beam accumulated in the resist on the substrate that corresponds to the second space pattern is closest to the development threshold in the case where drawing is performed in the variable shaped beam method based on the drawing data.

7. The electron beam drawing method according to claim 1, wherein the lithography original plate is a photomask, an EUV mask or a nanoimprint template.

8. An electron beam drawing apparatus comprising:
an electro-optical unit in which an electron gun outputs an electron beam, a shaping aperture shapes the electron beam, and a deflector deflects the shaped electron beam to irradiate a substrate with the electron beam;
a mechanical unit that includes a conveying part that conveys the substrate and a stage onto which the substrate is conveyed and mounted; and
a control unit that controls the electro-optical unit and the mechanical unit,
wherein the control unit
extracts a hot spot in a circuit pattern layout of the lithography original plate at which a circuit pattern in the circuit pattern layout and a preset hot spot drawing pattern agree with each other,
generates drawing data representing the circuit pattern layout with at least a part of the circuit pattern at the extracted hot spot replaced with a relieving drawing pattern, and
performs drawing on a resist applied to the substrate in the variable shaped beam method based on the drawing data,
the hot spot drawing pattern
includes first space patterns that are successively scanned with an electron beam and first line patterns that are adjacent to the first space patterns and are not scanned with the electron beam, and
the relieving drawing pattern
has the same size as the first space patterns and includes a second space pattern that is scanned with the electron beam, the second space pattern including a plurality of slits that are not scanned with the electron beam.

9. The electron beam drawing apparatus according to claim 8, wherein a part of the circuit pattern at the hot spot that corresponds to the first space patterns of the hot spot drawing pattern is replaced with the relieving drawing pattern.

10. The electron beam drawing apparatus according to claim 8, wherein in a case where the hot spot drawing pattern is drawn in the variable shaped beam method, the amount of energy of the electron beam accumulated in the resist on the substrate that corresponds to the first line patterns is greater than a preset development threshold, and
the development threshold is an upper limit value of the amount of accumulated energy that allows the resist applied to the substrate exposed to light to form a preset shape after development.

11. The electron beam drawing apparatus according to claim 10, wherein in the case where the hot spot drawing pattern is drawn in the variable shaped beam method, the amount of energy of the electron beam accumulated in the resist on the substrate that corresponds to the first space patterns is greater than the development threshold.

12. The electron beam drawing apparatus according to claim 8, wherein in the case where drawing is performed in the variable shaped beam method based on the drawing data, the amount of energy of the electron beam accumulated in the resist on the substrate that corresponds to the line patterns that are adjacent to the second space pattern and are not scanned with the electron beam is smaller than the development threshold.

13. The electron beam drawing apparatus according to claim 8, wherein the size and interval of the slits of the relieving drawing pattern are set so that the amount of energy of the electron beam accumulated in the resist on the substrate that corresponds to the second space pattern is closest to the development threshold in the case where drawing is performed in the variable shaped beam method based on the drawing data.

14. The electron beam drawing apparatus according to claim 8, wherein the lithography original plate is a photomask, an EUV mask or a nanoimprint template.

15. A data generating method comprising:
extracting a hot spot in a circuit pattern layout of the lithography original plate at which a circuit pattern in the circuit pattern layout and a preset hot spot drawing pattern agree with each other,
generating drawing data representing the circuit pattern layout with at least a part of the circuit pattern at the extracted hot spot replaced with a relieving drawing pattern, and
performing drawing on a resist applied to the substrate in the variable shaped beam method based on the drawing data, and
wherein the hot spot drawing pattern
includes first space patterns that are successively scanned with an electron beam and first line patterns that are adjacent to the first space patterns and are not scanned with the electron beam, and
wherein the relieving drawing pattern
has the same size as the first space patterns and includes a second space pattern that is scanned with the electron beam, the second space pattern including a plurality of slits that are not scanned with the electron beam.

16. The data generating method according to claim 15, wherein a part of the circuit pattern at the hot spot that corresponds to the first space patterns of the hot spot drawing pattern is replaced with the relieving drawing pattern.

17. The data generating method according to claim 15, wherein in a case where the hot spot drawing pattern is drawn in the variable shaped beam method, the amount of energy of the electron beam accumulated in the resist on the substrate that corresponds to the first line patterns is greater than a preset development threshold, and
the development threshold is an upper limit value of the amount of accumulated energy that allows the resist applied to the substrate exposed to light to form a preset shape after development.

18. The data generating method according to claim 17, wherein in the case where the hot spot drawing pattern is drawn in the variable shaped beam method, the amount of energy of the electron beam accumulated in the resist on the substrate that corresponds to the first space patterns is greater than the development threshold.

19. The data generating method according to claim 15, wherein in the case where drawing is performed in the variable shaped beam method based on the drawing data, the amount of energy of the electron beam accumulated in the resist on the substrate that corresponds to the line patterns that are adjacent to the second space pattern and are not scanned with the electron beam is smaller than the development threshold.

20. The data generating method according to claim 15, wherein the size and interval of the slits of the relieving drawing pattern are set so that the amount of energy of the electron beam accumulated in the resist on the substrate that corresponds to the second space pattern is closest to the development threshold in the case where drawing is performed in the variable shaped beam method based on the drawing data.
